(19) United States
(12) Patent Application Publication
(10) Pub. No.: US 2024/0305062 A1
(43) Pub. Date: Sep. 12, 2024

(54) WAVELENGTH MONITORING APPARATUS, WAVELENGTH MONITORING METHOD, AND WAVELENGTH LOCKER

(71) Applicant: NEC Corporation, Tokyo (JP)

(72) Inventor: Ryo MARUYAMA, Tokyo (JP)

(73) Assignee: NEC Corporation, Tokyo (JP)

(21) Appl. No.: 18/589,637

(22) Filed: Feb. 28, 2024

(30) Foreign Application Priority Data
Mar. 10, 2023 (JP) 2023-037233

(51) Int. Cl. H01S 5/0687; H01S 5/0225; H04B 10/572

(52) U.S. Cl. CPC H01S 5/0687; H01S 5/0225; H04B 10/572

(57) ABSTRACT

Provided are a wavelength monitoring apparatus, a wavelength monitoring method, and a wavelength locker that are capable of monitoring a wavelength of light by using a simple configuration. A first optical waveguide guides light of a single mode. An excitation structure excites light of a first mode and light of a second mode from the single-mode light propagating through the first optical waveguide. Through a second optical waveguide, the first-mode light and the second-mode light propagate. A first light receiver receives a combined wave of the first-mode light and the second-mode light. A wavelength analysis unit determines a wavelength of the single-mode light associated with light intensity of the combined wave received by the light receiver, based on information being acquired in advance and indicating a correspondence relationship between the light intensity and a wavelength of the combined wave received by the light receiver.

### INCORPORATION BY REFERENCE

This application is based upon and claims the benefit of priority from Japanese patent application No. 2023-37233, filed on Mar. 10, 2023, the disclosure of which is incorporated herein in its entirety by reference.

### TECHNICAL FIELD

The present disclosure relates to a wavelength monitoring apparatus, a wavelength monitoring method, and a wavelength locker.

### BACKGROUND ART

In a field of optical communication, a communication method using optical signals of various wavelengths, for example, communication using wavelength-multiplexed optical signals, is performed. Therefore, a wavelength tunable laser light source that outputs light of a desired wavelength has become an important device in recent optical communication. When the wavelength tunable laser light source is used, a wavelength monitoring apparatus that monitors a wavelength of output light is required.

As such a wavelength monitoring apparatus, an apparatus using an etalon (for example, U.S. Pat. No. 6,782,013, description, U.S. Pat. No. 5,798,859, description, and Tatsuya Kimoto et al., “Highly Reliable 40-mW, 25-GHz×20-ch Thermally Tunable DFB Laser Module Integrating Wavelength Monitor,” The Furukawa Electric Review, No. 112, July 2003, pages 1 to 4) and the like have been proposed. In addition, various wavelength monitoring methods have been proposed.

### SUMMARY

However, in a wavelength monitoring apparatus using an etalon, it is difficult to integrate the etalon with a light source apparatus, and a size of the system as a whole increases.

In view of the above-described circumstances, an example object of the present disclosure is to provide a wavelength monitoring apparatus, a wavelength monitoring method, and a wavelength locker that are capable of monitoring a wavelength of light by using a simple configuration.

In a first example aspect of the present disclosure, a wavelength monitoring apparatus includes:
a first optical waveguide configured to guide light of a single mode;
a first excitation means for exciting light of a first mode and light of a second mode that are different from each other, from the single-mode light propagating through the first optical waveguide;
a second optical waveguide through which the first-mode light and the second-mode light propagate;
a first light receiver configured to receive a first combined wave acquired by combining the first-mode light and the second-mode light; and
a determination means for determining a wavelength of the single-mode light associated with light intensity of the first combined wave received by the first light receiver, based on information being acquired in advance and indicating a correspondence relationship between the light intensity and a wavelength of the first combined wave received by the first light receiver.

In a second example aspect of the present disclosure, a wavelength monitoring method includes:
exciting light of a first mode and light of a second mode that are different from each other, from light of a single mode propagating through a first optical waveguide;
receiving a first combined wave acquired by combining the first-mode light and the second-mode light; and
determining a wavelength of the single-mode light associated with light intensity of the received first combined wave, based on information being acquired in advance and indicating a correspondence relationship between the light intensity and a wavelength of the first combined wave.

In a third example aspect of the present disclosure, a wavelength locker includes:
a wavelength tunable light source configured to output light of a single mode;
a wavelength monitoring apparatus configured to monitor a wavelength of the single-mode light being output from the wavelength tunable light source and output a monitoring result; and
a wavelength control means for instructing the wavelength tunable light source to control the wavelength of the single-mode light to be output, according to the monitoring result,
wherein the wavelength monitoring apparatus includes
   a first optical waveguide configured to guide the single-mode light being output from the wavelength tunable light source,
   a first excitation means for exciting light of a first mode and light of a second mode that are different from each other, from the single-mode light propagating through the first optical waveguide,
   a second optical waveguide through which the first-mode light and the second-mode light propagate,
   a first light receiver configured to receive a first combined wave acquired by combining the first-mode light and the second-mode light, and
   a determination means for determining a wavelength of the single-mode light associated with light intensity of the first combined wave received by the first light receiver, based on information being acquired in advance and indicating a correspondence relationship between the light intensity and a wavelength of the first combined wave received by the first light receiver.

### BRIEF DESCRIPTION OF DRAWINGS

The above and other aspects, features, and advantages of the present disclosure will become more apparent from the following description of certain example embodiments when taken in conjunction with the accompanying drawings, in which:

FIG. 1 is a diagram schematically illustrating a configuration of a wavelength monitoring apparatus according to a first example embodiment;

FIG. 2 is a diagram illustrating one example of an interference spectrum acquired by the wavelength monitoring apparatus according to the first example embodiment;

FIG. 3 is an enlarged view of the interference spectrum of FIG. 2;

FIG. 4 is a diagram schematically illustrating a configuration of a wavelength monitoring apparatus according to a second example embodiment;

FIG. 5 is a diagram schematically illustrating a configuration of a wavelength monitoring apparatus according to a third example embodiment;

FIG. 6 is a diagram illustrating one example of an interference spectrum acquired in advance according to the third example embodiment;

FIG. 7 is a flowchart of a wavelength determining operation using a long-period spectrum and a short-period spectrum;

FIG. 8 is a diagram illustrating a configuration example of a wavelength monitoring system for determining a wavelength of a single-mode light being monitored, by using a long-period spectrum and a short-period spectrum;

FIG. 9 is a diagram illustrating an example of an interference spectrum acquired in advance in the wavelength monitoring system;

FIG. 10 is a flowchart of the operation of determining the wavelength of light in the wavelength monitoring system;

FIG. 11 is a diagram schematically illustrating a configuration of a wavelength locker according to a fourth example embodiment; and

FIG. 12 is a flowchart of a wavelength control operation of the wavelength locker according to the fourth example embodiment.

### EXAMPLE EMBODIMENT

Hereinafter, example embodiments of the present disclosure will be described with reference to the drawings. In the drawings, the same element is denoted by the same reference numeral, and redundant descriptions are omitted as necessary.

### First Example Embodiment

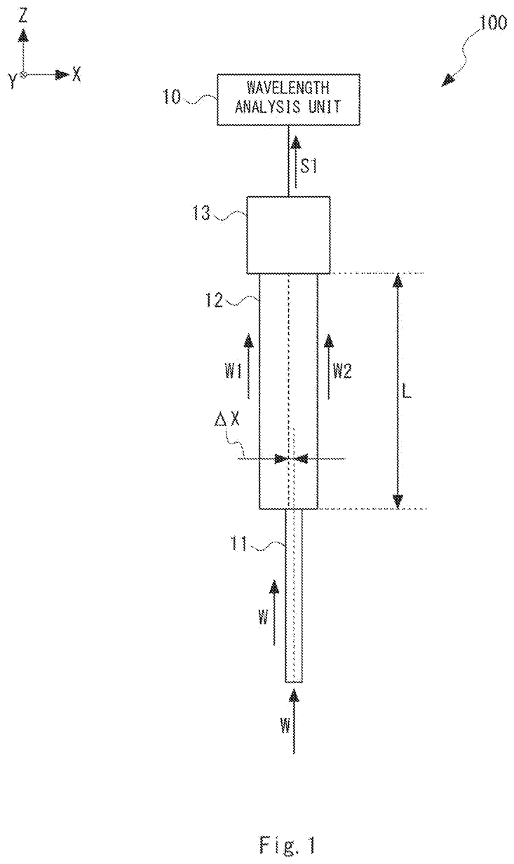

A wavelength monitoring apparatus according to a first example embodiment will be described. FIG. 1 schematically illustrates a configuration of a wavelength monitoring apparatus 100 according to the first example embodiment. The wavelength monitoring apparatus 100 includes a wavelength analysis unit 10, a first optical waveguide 11, a second optical waveguide 12, and a light receiver 13. Note that, in FIG. 1, a Z direction, which is a vertical direction from the bottom to the top of the page, is defined as a light propagation direction. In addition, a horizontal direction from left to right of the page is defined as an X direction, and a direction from the front to the back of the page is defined as a Y direction.

The first optical waveguide 11 is configured as a single-mode optical waveguide extending in the Z direction, and a single-mode light W from a wavelength tunable light source propagates therein in the Z direction.

The second optical waveguide 12 is configured as a two-mode optical waveguide extending in the Z direction and through which two modes of light propagate. An end portion of the first optical waveguide 11 on the +Z side is optically connected to an end portion of the second optical waveguide 12 on the −Z side. Herein, the second optical waveguide 12 is connected to the first optical waveguide 11 in such a way as to have a predetermined axis shift. In the present example, the second optical waveguide 12 is being connected in such a manner that the axis of the second optical waveguide 12 is offset from the axis of the first optical waveguide 11 by a predetermined offset ΔX in the X direction.

As a result, when the single-mode light W propagated through the first optical waveguide 11 enters the second optical waveguide 12, two modes of light W1 and W2 are excited and propagated. The excitation structure configured by connecting the first optical waveguide 11 and the second optical waveguide 12 in an axially shifted manner as described above may also be referred to as a first excitation means.

The light receiver 13 is optically connected to an end portion of the second optical waveguide 12 on the +Z side. As a result, the optical receiver 13 is able to receive interference light acquired by combining the two modes of light W1 and W2 that have propagated through the second optical waveguide 12. The light receiver 13 outputs a detection signal S1 indicating the light intensity of the interference light to the wavelength analysis unit 10. Note that the light receiver 13 may also be referred to as a first light receiver. Further, the interference light acquired by combining the two modes of light W1 and W2 may also be referred to as a first combined wave.

In the spectrum of the interference light, the light intensity periodically changes in accordance with the wavelength, and therefore, the signal intensity of the detection signal S1 also periodically changes in accordance with the wavelength. As for the relationship between the light intensity and the wavelength, for example, the spectrum of the interference light is able to be acquired by performing, as a preliminary preparation, observation of the light intensity while sweeping the wavelength of the input single-mode light, by using the wavelength monitoring apparatus according to the present example embodiment. In addition to the actual measurement, the spectrum of the interference light may be acquired by calculation, specifically, by calculation using equations [2] to [13]. The spectrum of the interference light may be acquired in advance in such a manner, and the wavelength analysis unit 10 is able to hold in advance information indicating a correspondence relationship between the wavelength of the single-mode light and the intensity of the interference light observed by the wavelength monitoring apparatus, for example, as table information.

The wavelength analysis unit 10 acquires the signal intensity of the detection signal S1, that is, the light intensity of the interference light, and analyzes and determines the wavelength of the single-mode light W by using the table information acquired in advance. Note that the wavelength analysis unit 10 may also be referred to as a determination means for determining a wavelength.

### [Two-Mode Excitation Structure]

In the present example embodiment, a connection method employing an axial shift and having a simple structure is being used as an excitation structure for two waveguide modes. By connecting the first optical waveguide 11 being a single-mode optical waveguide to the second optical waveguide 12 being a two-mode optical waveguide while applying a predetermined axial shift as described above, it is possible to excite the two modes of light at a predetermined light intensity ratio.

The combining ratio of the modes may be acquired from the overlap integration of the electric field distribution and may be expressed by the following equation, for example, as described in Ryo Maruyama, doctoral dissertation “Study on Design and Evaluation Method of Two Mode Optical Fiber Transmission Line,” 2019, Osaka Prefectural University.

$${η}_{M} = 10 log ( \frac{{\vert \int \int {E}_{I} \cdot {E}_{M} dxdy \vert}^{2}}{\int \int {\vert {E}_{I} \vert}^{2} dxdy \int \int {\vert {E}_{M} \vert}^{2} dxdy} ) ( dB ) \qquad [ 1 ]$$

Note that, the second optical waveguide 12 may be a multi-mode optical waveguide that guides two or more modes of light. However, since the third and subsequent modes of light become noise factors, it is desirable that only two modes of light are excited, or that the excitation ratio of the third and subsequent modes of light is sufficiently small (for example, 10% or less, more preferably 5% or less, and more preferably 1% or less) to be negligible.

As described above, by exciting the two modes of light to propagate through the second optical waveguide 12 being a suitably designed two-mode optical waveguide or a multi-mode optical waveguide, the two modes of light interfere with each other. The interference light is received by the light receiver 13, and thereby the interference spectrum may be acquired.

### [Spectrum of Interference Light]

Next, the spectrum of the interference light will be described. An optical waveguide is generally configured of regions called a core and a cladding, and the number of modes to be guided depends on the refractive index and dimensions of the core. In the case of a two-mode optical waveguide, such as the second optical waveguide 12, in which two modes of light are able to be guided, the electromagnetic field of each mode may be expressed by the following equation.

$${E}_{1} = √ {A}_{1} {e}^{- j {β}_{1} z} {e}^{j ω t} \qquad [ 2 ]$$

$${E}_{2} = √ {A}_{2} {e}^{- j {β}_{2} z} {e}^{j ω t} \qquad [ 3 ]$$

Herein, E₁ is an optical electric field of the first mode being one of the two modes, E₂ is an optical electric field of the second mode being the other of the two modes, √A₁ (where A₁>0) is an amplitude of the first mode, √A₂ (where A₂>0) is an amplitude of the second mode, β₁ is a propagation constant of the first mode, β₂ is a propagation constant of the second mode, ω is an angular frequency, z is a distance starting from an incident position of light of the optical waveguide, and tis a time.

The light intensity P of the combined wave when the light of the two modes interfere with each other in an overlapping manner may be expressed by the following equation.

$$P = {\vert {E}_{1} + {E}_{2} \vert}^{2} = {A}_{1} + {A}_{2} + 2 √ {A}_{1} √ {A}_{2} cos ( Δ β z ) \qquad [ 4 ]$$

Herein, Δβ represents a difference (propagation-constant difference) between β₁ and β₂.

Further, the propagation constants β₁ and β₂ may each be expressed by the following equations by using equivalent refractive indices n_{eq_1}, and n_{eq_2} of the first and second modes.

$${β}_{1} = 2 π {n}_{eq \_ 1} / λ \qquad [ 5 ]$$

$${β}_{2} = 2 π {n}_{eq \_ 2} / λ \qquad [ 6 ]$$

Herein, λ represents a wavelength of light.

The following equation is acquired by substituting equations [5] and [6] into equation [4].

$$P = {\vert {E}_{1} + {E}_{2} \vert}^{2} = {A}_{1} + {A}_{2} + 2 √ {A}_{1} √ {A}_{2} cos ( 2 π Δ {n}_{eq} / λ ) \qquad [ 7 ]$$

It is apparent from the third term on the right side of equation [7] (or equation [4]) that the combined wave exhibits a spectrum that varies periodically with respect to the wavelength.

A free spectral range (FSR) in this interference spectrum may be expressed by the following equation, as described in, for example, R. Ryf, et al., “Mode-Division Multiplexing Over 96 km of Few-Mode Fiber Using Coherent 6×6 MIMO Processing,” JOURNAL OF LIGHTWAVE TECHNOLOGY, VOL. 30, NO. 4, pages 521 to 531, 2012.

$$Δ λ = \frac{- {λ}_{0}^{2}}{Δ {n}_{g} ( λ ) L + λ} \qquad [ 8 ]$$

Herein, λ₀ is the center wavelength of the FSR, i.e., the center wavelength between two peaks of the interference spectrum. Δn_{g}(λ) represents the difference between the group refractive index n_{g_1}(λ) of the first mode and the group refractive index n_{g_2}(λ) of the second mode. The group refractive index n_{g_1}(λ) of the first mode and the group refractive index n_{g_2}(λ) of the second mode may be expressed by the following equations.

$${n}_{g \_ 1} ( λ ) = {n}_{eq \_ 1} ( λ ) - λ \frac{\partial {n}_{eq \_ 1}}{\partial λ} \qquad [ 9 ]$$

$${n}_{g \_ 2} ( λ ) = {n}_{eq \_ 2} ( λ ) - λ \frac{\partial {n}_{eq \_ 2}}{\partial λ} \qquad [ 10 ]$$

In such a way, it can be understood that by using two waveguide modes, an interference spectrum having a periodic change may be acquired, and that the period (FSR) thereof may be acquired from an eigenvalue (group refractive index) of each mode.

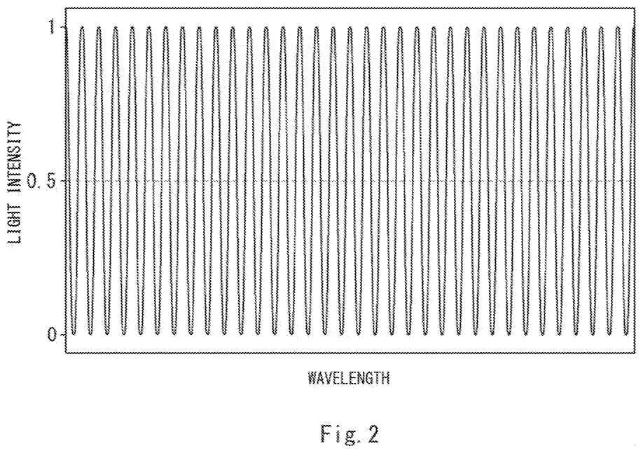

FIG. 2 illustrates one example of an interference spectrum acquired by the present configuration. As described above, in the present configuration, it is possible to acquire a periodically changing interference spectrum. Such interference spectrum is acquired in advance, and a table representing the association between the wavelength and the light intensity is also acquired in advance. Then, by monitoring a light intensity of light of an unknown wavelength and matching the monitored light intensity with information on the table, it is possible to determine the wavelength of the single-mode light W.

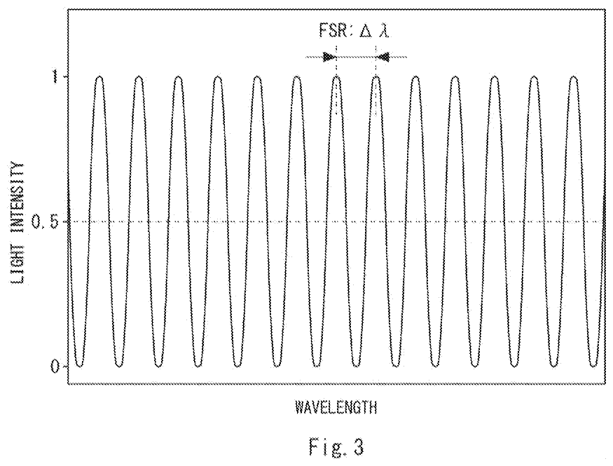

FIG. 3 illustrates an enlarged view of the interference spectrum of FIG. 2. In this example, a plurality of peaks appear, and a difference between two adjacent peaks among the plurality of peaks becomes the FSR Δλ described above.

In the interference spectrum of FIGS. 2 and 3, since a band in a range equal to or more that the FSR is monitored, a wavelength associated with the same light intensity is present in addition to the wavelength to be monitored. However, when monitoring the wavelength of light being output from a wavelength tunable light source such as a laser apparatus, the approximal value of the wavelength is generally known. Therefore, it is possible to accurately monitor the wavelength of the light W to be monitored, based on the known approximate value of the wavelength.

Note that, there are various methods for monitoring a wavelength, and there are methods using fiber gratings and ring resonators other than the method using an etalon described above. However, in a case where a fiber grating is used, it is difficult to perform integration with a light source apparatus, and an adaptable band becomes narrow. In a case where a ring resonator is used, although an interference spectrum of a narrow FSR may be acquired and a high-resolution monitoring apparatus may be achieved, there is a disadvantage that the linearity of the spectrum with respect to the wavelength is low.

However, according to the present configuration, it is possible to accurately monitor the wavelength of the light to be monitored while avoiding problems that may occur in a wavelength monitoring apparatus using the aforementioned other methods.

### Second Example Embodiment

In the first example embodiment, a configuration in which the spectrum of the interference light is observed as it is has been described. However, for example, when the light intensity of the incident light W fluctuates, the intensity of the spectrum changes overall. Therefore, there is a possibility that the wavelength monitoring accuracy is affected by the light intensity of the incident light. Therefore, in the present example embodiment, a wavelength monitoring apparatus capable of monitoring a wavelength without being affected by the light intensity of the incident light will be described.

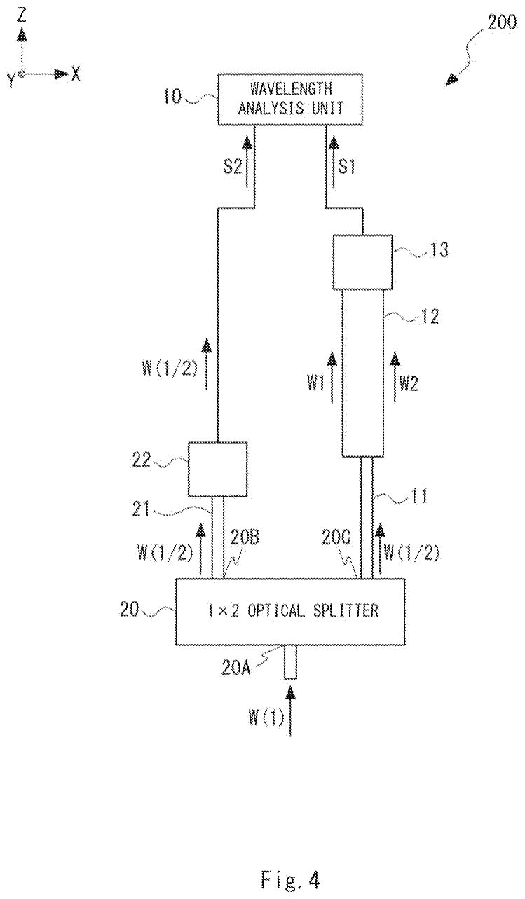

FIG. 4 schematically illustrates a configuration of a wavelength monitoring apparatus 200 according to a second example embodiment. The wavelength monitoring apparatus 200 has a configuration in which a power splitter 20, an optical waveguide 21, and a light receiver 22 are added to the wavelength monitoring apparatus 100 according to the first example embodiment.

The power splitter 20 is a 1×2 optical splitter having one input port 20A and two output ports 20B and 20C, wherein the power splitter 20 splits single-mode light W input to the input port 20A into two beams of light having the same light intensity and outputs the beams of light through the two output ports 20B and 20C. When the light intensity of the single-mode light W input to the input port 20A is 1, single-mode light W having a ½ light intensity is output from the output port 20B, and single-mode light W having a ½ light intensity is also output from the output port 20C. Note that the power splitter 20 may also be referred to as a splitting means.

The output port 20B is connected to the light receiver 22 by the single-mode optical waveguide 21. Thus, the light receiver 22 receives only the single-mode light W having the ½ light intensity. The light receiver 22 outputs a detection signal S2 indicating the light intensity of the received light to a wavelength analysis unit 10. Herein, the optical waveguide 21 and the light receiver 22 may also be simply referred to as a light receiving means or a third light receiver. Further, the light W being output from the output port 20B of the power splitter 20 to the optical waveguide 21 may also be referred to as reference light.

The output port 20C is connected to an end portion of a first optical waveguide 11 on the −Z side. Therefore, the single-mode light W having the ½ light intensity is input to the first optical waveguide 11. Herein, the light W being input to the first optical waveguide 11 may also be referred to as first light. The single-mode light W propagates through the first optical waveguide 11, and the two modes of light are excited at a connection portion between the first optical waveguide 11 and a second optical waveguide 12. As a result, the interference spectrum may be acquired in a manner similar to that in the first example embodiment.

The wavelength analysis unit 10 corrects, by using the light intensity of the single-mode light W received by the light receiver 22, light intensity of the interference spectrum acquired by a light receiver 13, according to detection signals S1 and S2. More specifically, the wavelength analysis unit 10 performs processing of normalizing the light intensity of the interference spectrum acquired by the light receiver 13 by the light intensity of the single-mode light W received by the light receiver 22. The light intensity of the light incident on the power splitter 20 is defined as 2P₀, the light intensity of the light received by the second light receiver 22 is defined as P_{REF}, and the light intensity of the interference light received by the light receiver 13 is defined as P. Note that it is assumed that the loss during the propagation of light from the power splitter 20 to the light receiver 13 and the light receiver 22 is negligibly small. At this time, the light intensity P_{REF} of the light received by the light receiver 22 may be expressed by the following equation.

$${P}_{REF} = {P}_{0} \qquad [ 11 ]$$

The light intensity P of the interference light received by the light receiver 13 may be expressed by the following equation.

$$P = {P}_{0} η + {P}_{0} γ + 2 \sqrt{{P}_{0} η} \sqrt{{P}_{0} γ} cos ( 2 π Δ {n}_{eq} / λ ) \qquad [ 12 ]$$

Herein, η and γ are power conversion efficiencies to each mode.

A normalized light intensity Pₙₒᵣ may be calculated by dividing the light intensity P of the interference light received by the light receiver 13 by the light intensity P_{REF} of the light received by the light receiver 22.

$$\begin{matrix}{P}_{nor} = \frac{P}{{P}_{REF}} \\ = \frac{{P}_{0} η + {P}_{0} γ + 2 \sqrt{{P}_{0} η} \sqrt{{P}_{0} γ} cos ( 2 π Δ {n}_{eq} / λ )}{{P}_{0}} \\ = η + γ + 2 \sqrt{η} \sqrt{γ} cos ( 2 π Δ {n}_{eq} / λ )\end{matrix} \qquad [ 13 ]$$

Thus, by normalizing the light intensity of the interference spectrum, it is possible to acquire an interference spectrum independent of the incident light intensity. According to the present configuration, it is possible to more accurately monitor the wavelength of light.

### Third Example Embodiment

In the first example embodiment, description is made assuming that an approximate value of the oscillation wavelength of the light source is prepared in advance, and a peak to be observed is determined based on the approximate value. However, it is also possible to monitor the wavelength of the light without depending on the approximate value of the oscillation wavelength of the light source.

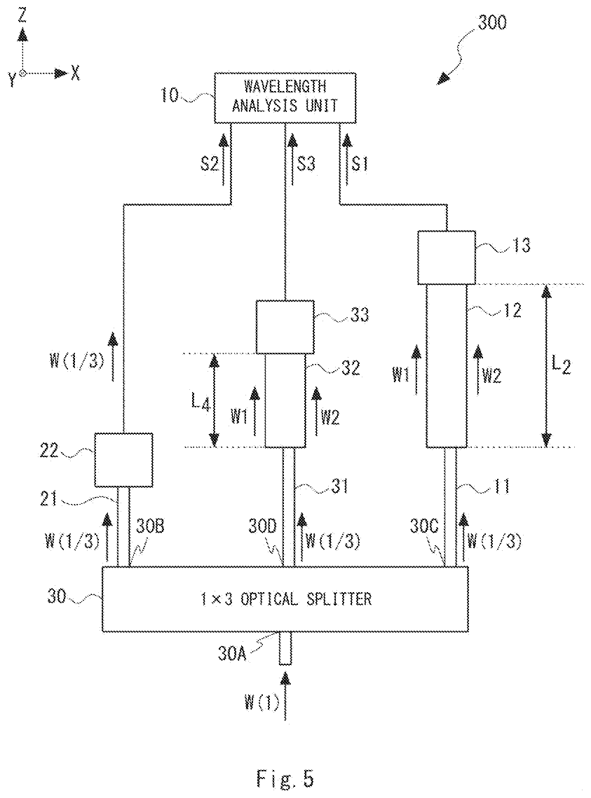

FIG. 5 schematically illustrates a configuration of a wavelength monitoring apparatus 300 according to a third example embodiment. The wavelength monitoring apparatus 300 has a configuration in which the power splitter 20 of the wavelength monitoring apparatus 200 according to the second example embodiment is substituted with a power splitter 30, and a third optical waveguide 31, a fourth optical waveguide 32, and a light receiver 33 are added.

The power splitter 30 is a 1×3 optical splitter having one input port 30A and three output ports 30B to 30D, wherein the power splitter 30 splits single-mode light W input to the input port 30A into three light beams having the same light intensity, and outputs each of the light beams through the three output ports 30B to 30D. When the light intensity of the single-mode light W input to the input port 30A is 1, single-mode light W having a ⅓ light intensity is output from each of the output ports 30B to 30D. The power splitter 30 may also be referred to as a splitting means.

Similarly to the output port 20B of the wavelength monitoring apparatus 200, the output port 30B is connected to an optical receiver 22 by a single-mode optical waveguide 21. Thus, the light receiver 22 receives only the single-mode light W having the ⅓ light intensity.

Similarly to the output port 20C of the wavelength monitoring apparatus 200, the output port 30C is connected to an end portion of a first optical waveguide 11 on the −Z side. Thus, the single-mode light W having the ⅓ light intensity is input to the first optical waveguide 11. Therefore, similarly to the first and second example embodiments, a wavelength analysis unit 10 is able to acquire the interference spectrum, based on the result of the light reception by a light receiver 13.

The output port 30D is connected to an end portion of the third optical waveguide 31 on the −Z side, the third optical waveguide 31 being a single-mode optical waveguide, and the single-mode light W having the ⅓ light intensity is input thereto. Herein, the light W input to the third optical waveguide 31 may also be referred to as second light.

An end portion of the third optical waveguide 31 on the +Z side is connected to an end portion of the fourth optical waveguide 32 on the −Z side, the fourth optical waveguide 32 being a two-mode optical waveguide (or a multi-mode optical waveguide), with the optical axes of the optical waveguides being shifted by a predetermined offset. Such an excitation structure configured by connecting the third optical waveguide 31 and the fourth optical waveguide 32 in an axially shifted manner may also be referred to as a second excitation means. An end portion of the fourth optical waveguide 32 on the +Z side is connected to the optical receiver 33.

The optical receiver 33 receives interference light acquired by combining two modes of light W1 and W2 that propagated through the fourth optical waveguide 32, and outputs a detection signal S3 indicating the light intensity of the received light to the wavelength analysis unit 10. Thus, the wavelength analysis unit 10 is able to acquire an interference spectrum of the interference light acquired by combining the two modes of light W1 and W2 that propagated through the fourth optical waveguide 32. Herein, the interference light acquired by combining the two modes of light W1 and W2 that propagated through the fourth optical waveguide 32 may also be referred to as a second combined wave. The interference spectrum acquired by the wavelength analysis unit 10, based on the result of the light reception by the light receiver 33 may also be referred to as a second spectrum.

Herein, referring to equation [8], it can be seen that the longer the length L of the optical waveguide through which the two modes of light propagate, the smaller the FSR becomes. That is, by increasing the length L of the optical waveguide through which the two modes of light propagate, an interference spectrum that fluctuates in a short period is acquired, and by shortening the length L of the optical waveguide through which the two modes of light propagate, an interference spectrum that fluctuates in a long period is acquired.

In the present configuration, since two interference spectra having different light intensity fluctuation periods are acquired, a second optical waveguide 12 is set to have a length enabling acquisition of a short-period spectrum. In addition, the fourth optical waveguide 32 has a length enabling acquisition of a long-period spectrum. That is, when the length of the second optical waveguide 12 is L₂ and the length of the fourth optical waveguide 32 is L₄, L₂>L₄ is satisfied.

Thus, the third optical waveguide 31, the fourth optical waveguide 32, and the light receiver 33 constitute a low-resolution monitoring unit capable of monitoring a wide wavelength range while having a small power change rate with respect to the wavelength. In addition, the first optical waveguide 11, the second optical waveguide 12, and the light receiver 13 constitute a high-resolution monitoring unit capable of monitoring the wavelength more finely while having a large power change rate with respect to the wavelength in a local region.

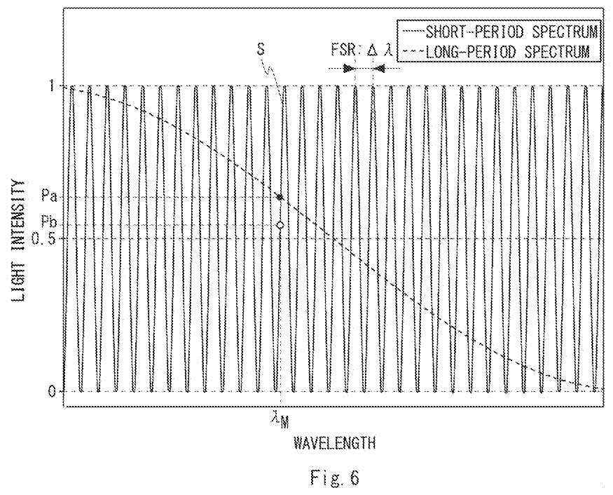

FIG. 6 illustrates one example of an interference spectrum acquired in advance and being used in the present configuration. In this example, a short-period spectrum indicated by a solid line and a long-period spectrum indicated by a broken line are acquired in advance.

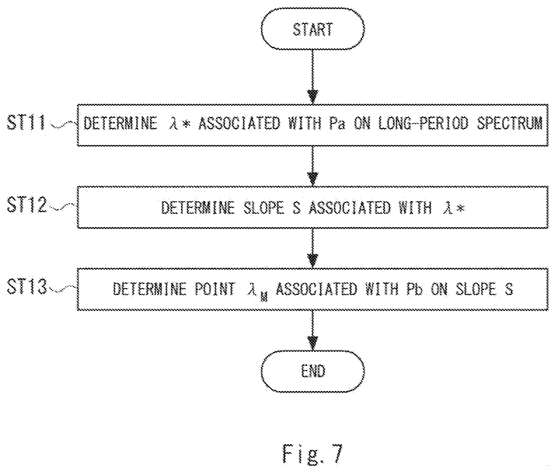

Hereinafter, a wavelength determination operation using the long-period spectrum and the short-period spectrum will be described. FIG. 7 illustrates a flowchart of the wavelength determination operation using the long-period spectrum and the short-period spectrum.

### Step ST11

Acquire a light intensity Pa of the light receiver 33 on the long-period spectrum side, match the light intensity Pa with a table indicating a correspondence relationship between the light intensity and the wavelength of the long-period spectrum acquired in advance, and roughly determine the wavelength of the light W. Herein, the determined wavelength is represented by λ*.

### Step ST12

Next, determine a slope S associated with λ* in the short-period spectrum.

### Step ST13

In the slope S of the short-period spectrum, acquire a light intensity Pb of the light receiver 13 on the short-period spectrum side, match Pb with a table indicating a correspondence relationship between the light intensity and the wavelength of the short-period spectrum acquired in advance, and determine the wavelength λ_{M} of the light W.

According to the present configuration, after roughly determining the wavelength of the single-mode light to be monitored, by further referring to the short-period spectrum near the determined wavelength, the wavelength of the single-mode light W may be monitored with high resolution, similarly to the second example embodiment.

As described above, according to the present configuration, wavelength may be automatically and accurately monitored by determining the approximate wavelength of the monitoring target light by the long-period spectrum acquired by a low-resolution monitoring unit, and referring to the peak near the approximate wavelength determined in the short-period spectrum acquired by a high-resolution monitoring unit.

In the example of FIG. 6, a case has been described in which the long-period spectrum changes monotonically for half a period, that is, from a local maximum to a local minimum, in the wavelength range to be monitored. However, depending on the design of the low-resolution monitor unit and the high-resolution monitor unit and the setting of the monitoring range of the wavelength of light, a case where the long-period spectrum is acquired in a range larger than half a period may be assumed. Even in such a case, similarly to the example of FIG. 6, the wavelength of the single-mode light W to be monitored may be automatically and accurately monitored by using the long-period spectrum and the short-period spectrum.

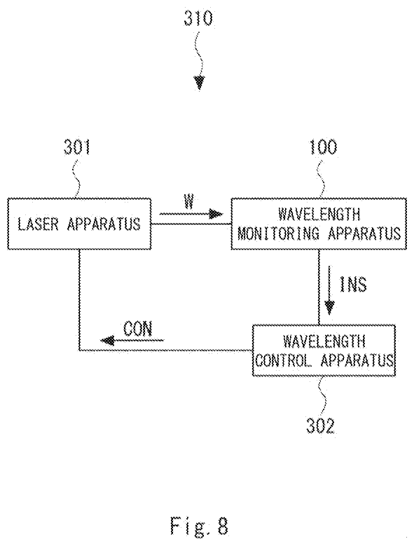

FIG. 8 illustrates a configuration example of a wavelength monitoring system 310 that determines a wavelength of a single-mode light to be monitored by using a long-period spectrum and a short-period spectrum. In the wavelength monitoring system 310, the wavelength monitoring apparatus 100 according to the first example embodiment, a laser apparatus 301, and a wavelength control apparatus 302 cooperatively monitor the wavelength of light.

The laser apparatus 301 is configured as a wavelength tunable light source capable of outputting a single-mode light W being a laser beam. The laser apparatus 301 may be configured as a wavelength tunable light source having various configurations, and may be configured by, for example, a semiconductor laser element, an external resonator that converts light from the semiconductor laser element into light of a single wavelength, and the like.

The wavelength control apparatus 302 receives a control instruction INS from the wavelength monitoring apparatus 100, and, in order to perform wavelength control in accordance with the control instruction INS, outputs a control signal CON to the laser apparatus 301.

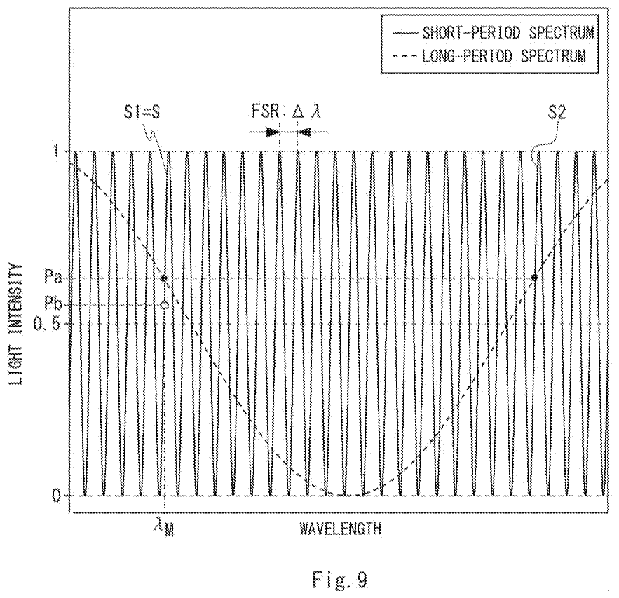

Next, FIG. 9 illustrates an example of an interference spectrum acquired in advance in the wavelength monitoring system 310. In such an example, similarly to FIG. 6, a short-period spectrum indicated by a solid line and a long-period spectrum indicated by a broken line are acquired in advance. However, as compared with FIG. 6, in the long-period spectrum, the light intensity changes for approximately one period in the monitoring range of the wavelength, that is, the light intensity changes from the local maximum to the local minimum, and then changes again to the local maximum.

As shown in FIG. 9, when the long-period spectrum changes by one period, there are a range wherein the light intensity monotonically decreases with respect to the wavelength as in the left half, and a range wherein the light intensity monotonically increases with respect to the wavelength as in the right half. Herein, there are two points corresponding to a measurement value P_{M} of the light intensity. In FIG. 9, a point Pa1 in the range where the light intensity monotonically decreases and a point Pa2 in the range where the light intensity monotonically increases correspond to the measurement value P_{M}.

In such a case, there are two wavelengths as candidates for the wavelength of the single-mode light W being monitored, associated with the point Pa1 and the point Pa2 appearing on the long-period spectrum. Therefore, in the present configuration, in order to determine the wavelength of the light being monitored, it is required to identify which of the point Pa1 and the point Pa2 is associated with the wavelength of the single-mode light W being monitored.

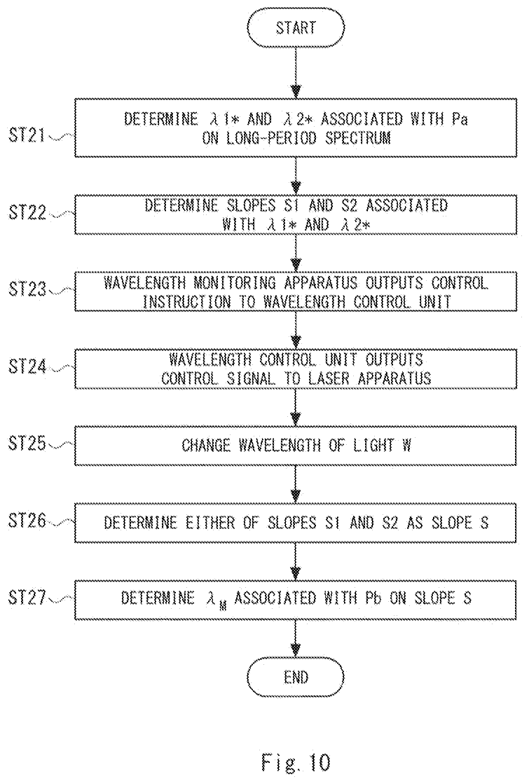

Hereinafter, a wavelength monitoring operation performed in the wavelength monitoring system 310 will be described. FIG. 10 illustrates a flowchart of an operation of determining a wavelength of light in the wavelength monitoring system 310. In a state where the wavelength monitoring apparatus 100 monitors the wavelength of the single-mode light W output from the laser apparatus 301, the following processing is performed.

### Step ST21

Acquire the light intensity Pa of the light receiver 33 on the long-period spectrum side, match Pa with a table acquired in advance, the table indicating a correspondence relationship between the light intensity and the wavelength in the long-period spectrum, and roughly determine the wavelength of the light W. Herein, since there are a monotonically decreasing range and a monotonically increasing range in the long period spectrum, λ1* on the short-wavelength side and λ2* on the long-wavelength side are roughly determined.

### Step ST22

Next, determine a slope S1 associated with λ1* and a slope S2 associated with λ2* in the short-period spectrum.

### Step ST23

The wavelength monitoring apparatus 100 outputs, to the wavelength control apparatus 302, the control instruction INS for controlling the wavelength of the single-mode light W being output from the laser apparatus 301.

### Step ST24

The wavelength control unit 302 outputs the control signal CON to the laser apparatus 301 in order to change the wavelength of the single-mode light W being output from the laser apparatus 301, based on the control instruction INS.

### Step ST25

According to the control signal CON, the laser apparatus 301 changes, to the short-wavelength side or the long-wavelength side, the wavelength of the single-mode light W to be output, and then returns the wavelength to the original wavelength Pa.

### Step ST26

The wavelength monitoring apparatus 100 observes the change in the light intensity while the wavelength of the single-mode light W being output from the laser apparatus 301 is changing, and determines, according to the observation result, the slope S to be used for determining the wavelength from the slopes S1 and S2. Herein, it is assumed that the light intensity observed by the wavelength monitoring apparatus 100 decreases when the wavelength of the single-mode light W being output from the laser apparatus 301 is changed to the long-wavelength side. In such a case, in FIG. 9, the slope S1 in the range where the long-period spectrum monotonically decreases corresponds to the slope S. Therefore, as illustrated in FIG. 9, the wavelength monitoring apparatus 100 determines the slope S1 on the short-wavelength side as the slope S to be used for determining the wavelength of the single-mode light W being monitored.

### Step ST27

Similarly to step S13 of FIG. 7, acquire, in the slope S of the short-period spectrum, light intensity Pb of the light receiver 13 on the short-period spectrum side, match Pb with a table acquired in advance, the table indicating a correspondence relationship between the light intensity and the wavelength in the short-period spectrum, and determine the wavelength λ_{M} of the light W.

As described above, according to the present configuration, it is possible to automatically and accurately monitor the wavelength of the single-mode light W being monitored, even in a case where the monitoring range of the wavelength is equal to or more than half the period of the long-period spectrum, more specifically, one period.

### Fourth Example Embodiment

In the above-described example embodiment, a wavelength monitoring apparatus for monitoring a wavelength of a single-mode light W, which is laser light being output from a laser apparatus, has been described. By using such a wavelength monitoring apparatus, it is also possible to configure a wavelength locker for controlling the wavelength of the single-mode light W being output by the laser apparatus.

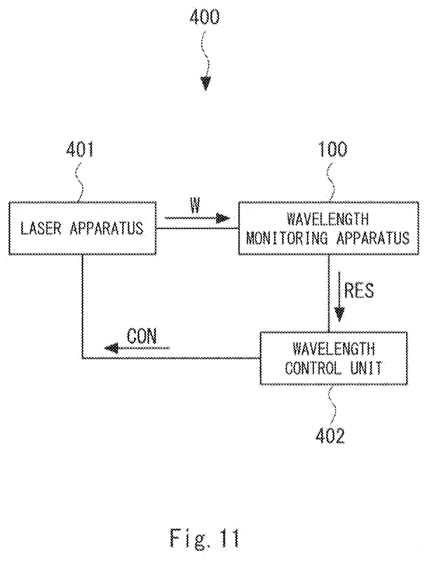

FIG. 11 schematically illustrates a configuration of a wavelength locker 400 according to a fourth example embodiment. The wavelength locker 400 includes a laser apparatus 401, a wavelength control unit 402, and a wavelength monitoring apparatus 100.

As described above, the wavelength monitoring apparatus 100 according to the first example embodiment monitors the wavelength of the single-mode light W output from the laser apparatus 401, and outputs a monitoring result RES to the wavelength control unit 402.

The laser apparatus 401 is similar to the laser apparatus 301 of FIG. 8, and therefore, repetitive description thereof will be omitted.

The wavelength control unit 402 outputs a control signal CON to the laser apparatus 401 in order to instruct the laser apparatus 401 to perform wavelength control based on the monitoring result RES.

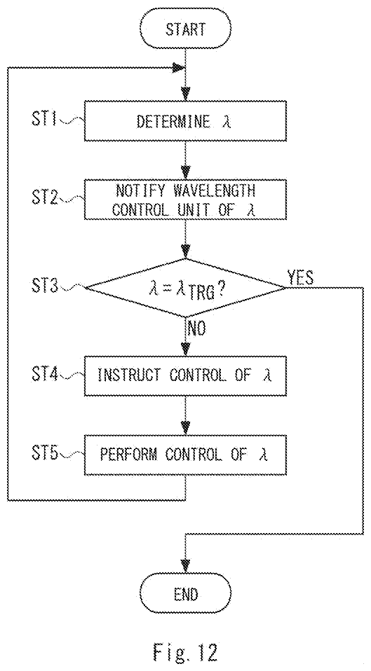

Hereinafter, a wavelength control operation of the wavelength locker 400 will be described. FIG. 12 illustrates a flow of the wavelength control operation of the wavelength locker 400 according to the fourth example embodiment.

### Step ST1

The wavelength monitoring apparatus 100 determines a wavelength λ of a single-mode light W.

### Step ST2

The wavelength monitoring apparatus 100 outputs the monitoring result RES of the wavelength λ to the wavelength control unit 402, and notifies the wavelength control unit 402 of the value of the wavelength λ.

### Step ST3

The wavelength control unit 402 compares the determined wavelength λ with a target wavelength λ_{TRG} of light being output from the laser apparatus 401. At this time, determination of whether the determined wavelength λ matches the target wavelength λ_{TRG} may be performed by determining whether the wavelength λ falls within a predetermined range including the target wavelength λ_{TRG}.

If the determined wavelength λ and the target wavelength λ_{TRG} match, the wavelength control processing is ended.

### Step ST4

If the determined wavelength λ and the target wavelength λ_{TRG} do not match, the control signal CON for instructing a wavelength control is output to the laser apparatus 401 in order to eliminate a difference between the determined wavelength λ and the target wavelength λ_{TRG}.

### Step ST5

The laser apparatus 401 performs wavelength control, according to the control signal CON. Thereafter, the process returns to step ST1.

By performing the above-described looping process in steps ST1 to ST5, the wavelength λ of the single-mode light W being output from the laser apparatus 401 may be automatically matched with the target wavelength λ_{TRG}.

As described above, according to the present configuration, a wavelength locker including a wavelength monitoring apparatus may be configured to control a wavelength of light being output from a laser apparatus to a desired wavelength.

Note that, in the present example embodiment, description is made assuming that the wavelength locker is configured by using the wavelength monitoring apparatus 100 according to the first example embodiment, but this is merely an example. Needless to say, the wavelength monitoring apparatus 200 according to the second example embodiment or the wavelength monitoring apparatus 300 according to the third example embodiment may be used for configuring the wavelength locker.

### Other Example Embodiments

Note that, the present disclosure is not limited to the above-described example embodiments, and may be appropriately modified without departing from the spirit thereof. For example, the means for exciting the two modes of light from the single mode of light is not limited to connecting two optical waveguides in an axially shifted manner as described above. For example, a mathematical process (Fourier analysis) as described in M. Inoue et al., “Differential group delay measurements of few-mode fibers using an interferometric technique,” IEICE Communications Express, Vol. 9, No. 7, pages 330 to 335, 2020 may be performed on the waveforms acquired by exciting multiple modes of light by various excitation means and receiving resulting interference light, thereby removing the effects of the third and subsequent modes and acquiring the interference spectrum of only two modes.

In the above-described example embodiment, description is made assuming that a power splitter splits the input light into a plurality of beams of light having the same light intensity, but this is merely an example. The power splitter may split the input light into a plurality of beams of light having a predetermined intensity ratio being different from the same light intensity.

Each of the above-described example embodiments can be combined as desirable by one of ordinary skill in the art.

An example advantage according to the above-described example embodiments is to provide a wavelength monitoring apparatus, a wavelength monitoring method, and a wavelength locker that are capable of monitoring a wavelength of light by using a simple configuration.

While the disclosure has been particularly shown and described with reference to example embodiments thereof, the disclosure is not limited to these example embodiments. It will be understood by those of ordinary skill in the art that various changes in form and details may be made therein without departing from the spirit and scope of the present disclosure as defined by the claims.

The whole or part of the example embodiments disclosed above can be described as, but not limited to, the following supplementary notes.

### (Supplementary Note 1)

A wavelength monitoring apparatus including:
a first optical waveguide configured to guide light of a single mode;
a first excitation means for exciting light of a first mode and light of a second mode that are different from each other, from the single-mode light propagating through the first optical waveguide;
a second optical waveguide through which the first-mode light and the second-mode light propagate;
a first light receiver configured to receive a first combined wave acquired by combining the first-mode light and the second-mode light; and
a determination means for determining a wavelength of the single-mode light associated with light intensity of the first combined wave received by the first light receiver, based on information being acquired in advance and indicating a correspondence relationship between the light intensity and a wavelength of the first combined wave received by the first light receiver.

### (Supplementary Note 2)

The wavelength monitoring apparatus according to supplementary note 1, wherein the first excitation means is formed by optically connecting the first optical waveguide and the second optical waveguide by shifting, by a predetermined amount, an optical axis of the first optical waveguide and an optical axis of the second optical waveguide in a direction orthogonal to the optical axis of the first optical waveguide and the optical axis of the second optical waveguide.

### (Supplementary Note 3)

The wavelength monitoring apparatus according to supplementary note 1 or 2, further including:
a splitting means for splitting the single-mode light into first light and reference light that have a predetermined light intensity ratio, and outputting the first light to the first optical waveguide; and
a light receiving means for receiving the reference light,
wherein the determination means corrects the light intensity of the first combined wave received by the first light receiver, based on the light intensity of the reference light received by the light receiving means.

### (Supplementary Note 4)

The wavelength monitoring apparatus according to supplementary note 1 or 2, further including:
a splitting means for splitting the single-mode light into a plurality of beams of light having a predetermined light intensity ratio, outputting first light among the plurality of beams of light to the first optical waveguide, and outputting second light;
a third optical waveguide configured to guide the second light;
a second excitation means for exciting the first-mode light and the second-mode light from the second light propagating through the third optical waveguide;
a fourth optical waveguide through which the first-mode light and the second-mode light that are excited by the second excitation means propagate, the fourth optical waveguide being shorter than the second optical waveguide; and
a second light receiver configured to receive a second combined wave acquired by combining the first-mode light and the second-mode light that are propagated through the fourth optical waveguide,
wherein the determination means
   performs processing of determining a wavelength of the single-mode light associated with light intensity of the second combined wave received by the second light receiver, based on information being acquired in advance and indicating a correspondence relationship between the light intensity and a wavelength of the second combined wave received by the second light receiver, and
   determines, based on the processing, information to be referred to among a correspondence relationship, being acquired in advance, between the light intensity and a wavelength of the first combined wave received by the first light receiver, and determines, based on the determined information, a wavelength of the single-mode light associated with the light intensity of the first combined wave received by the first light receiver.

### (Supplementary Note 5)

The wavelength monitoring apparatus according to supplementary note 4, wherein the second excitation means is formed by optically connecting the third optical waveguide and the fourth optical waveguide by shifting, by a predetermined amount, an optical axis of the third optical waveguide and an optical axis of the fourth optical waveguide in a direction orthogonal to the optical axis of the third optical waveguide and the optical axis of the fourth optical waveguide.

### (Supplementary Note 6)

The wavelength monitoring apparatus according to supplementary note 4, further including a light receiving means for receiving reference light among the plurality of beams of light,
wherein the determination means corrects light intensity of the first combined wave received by the first light receiver and light intensity of the second combined wave received by the second light receiver, based on light intensity of the reference light received by the light receiving means.

### (Supplementary Note 7)

A wavelength monitoring method including:
exciting light of a first mode and light of a second mode that are different from each other, from light of a single mode propagating through a first optical waveguide;
receiving a first combined wave acquired by combining the first-mode light and the second-mode light; and
determining a wavelength of the single-mode light associated with light intensity of the received first combined wave, based on information being acquired in advance and indicating a correspondence relationship between the light intensity and a wavelength of the first combined wave.

### (Supplementary Note 8)

A wavelength locker including:
a wavelength tunable light source configured to output light of a single mode;
a wavelength monitoring apparatus configured to monitor a wavelength of the single-mode light being output from the wavelength tunable light source and output a monitoring result; and
a wavelength control means for instructing the wavelength tunable light source to control a wavelength of the single-mode light to be output, according to the monitoring result,
wherein the wavelength monitoring apparatus includes
   a first optical waveguide configured to guide the single-mode light being output from the wavelength tunable light source,
   a first excitation means for exciting light of a first mode and light of a second mode that are different from each other, from the single-mode light propagating through the first optical waveguide,
   a second optical waveguide through which the first-mode light and the second-mode light propagate,
   a first light receiver configured to receive a first combined wave acquired by combining the first-mode light and the second-mode light, and
   a determination means for determining a wavelength of the single-mode light associated with light intensity of the first combined wave received by the first light receiver, based on information being acquired in advance and indicating a correspondence relationship between the light intensity and a wavelength of the first combined wave received by the first light receiver.

What is claimed is:

1. A wavelength monitoring apparatus comprising:
a first optical waveguide configured to guide light of a single mode;
a first excitation structure configured to excite light of a first mode and light of a second mode that are different from each other, from the single-mode light propagating through the first optical waveguide;
a second optical waveguide through which the first-mode light and the second-mode light propagate;
a first light receiver configured to receive a first combined wave acquired by combining the first-mode light and the second-mode light; and
a wavelength analysis unit configured to determine a wavelength of the single-mode light associated with light intensity of the first combined wave received by the first light receiver, based on information being acquired in advance and indicating a correspondence relationship between the light intensity and a wavelength of the first combined wave received by the first light receiver.

2. The wavelength monitoring apparatus according to claim 1, wherein the first excitation structure is formed by optically connecting the first optical waveguide and the second optical waveguide by shifting, by a predetermined amount, an optical axis of the first optical waveguide and an optical axis of the second optical waveguide in a direction orthogonal to the optical axis of the first optical waveguide and the optical axis of the second optical waveguide.

3. The wavelength monitoring apparatus according to claim 1, further comprising:
a splitter configured to split the single-mode light into first light and reference light that have a predetermined light intensity ratio, and outputting the first light to the first optical waveguide; and
a light receiver configured to receive the reference light,
wherein the wavelength analysis unit corrects the light intensity of the first combined wave received by the first light receiver, based on the light intensity of the reference light received by the light receiver.

4. The wavelength monitoring apparatus according to claim 1, further comprising:
a splitter configured to split the single-mode light into a plurality of beams of light having a predetermined light intensity ratio, outputting first light among the plurality of beams of light to the first optical waveguide, and outputting second light;
a third optical waveguide configured to guide the second light;
a second excitation structure configured to excite the first-mode light and the second-mode light from the second light propagating through the third optical waveguide;
a fourth optical waveguide through which the first-mode light and the second-mode light that are excited by the second excitation structure propagate, the fourth optical waveguide being shorter than the second optical waveguide; and
a second light receiver configured to receive a second combined wave acquired by combining the first-mode light and the second-mode light that are propagated through the fourth optical waveguide,
wherein the wavelength analysis unit
performs processing of determining a wavelength of the single-mode light associated with light intensity of the second combined wave received by the second light receiver, based on information being acquired in advance and indicating a correspondence relationship between the light intensity and a wavelength of the second combined wave received by the second light receiver, and
determines, based on the processing, information to be referred to among a correspondence relationship, being acquired in advance, between the light intensity and a wavelength of the first combined wave received by the first light receiver, and determines, based on the determined information, a wavelength of the single-mode light associated with the light intensity of the first combined wave received by the first light receiver.

5. The wavelength monitoring apparatus according to claim 4, wherein the second excitation structure is formed by optically connecting the third optical waveguide and the fourth optical waveguide by shifting, by a predetermined amount, an optical axis of the third optical waveguide and an optical axis of the fourth optical waveguide in a direction orthogonal to the optical axis of the third optical waveguide and the optical axis of the fourth optical waveguide.

6. The wavelength monitoring apparatus according to claim 4, further comprising light receiver configured to receive reference light among the plurality of beams of light,
wherein the wavelength analysis unit corrects light intensity of the first combined wave received by the first light receiver and light intensity of the second combined wave received by the second light receiver, based on light intensity of the reference light received by the light receiver.

7. A wavelength monitoring method comprising:
by a first excitation structure, exciting light of a first mode and light of a second mode that are different from each other, from light of a single mode propagating through a first optical waveguide;
receiving a first combined wave acquired by combining the first-mode light and the second-mode light; and
determining a wavelength of the single-mode light associated with light intensity of the received first combined wave, based on information being acquired in advance and indicating a correspondence relationship between the light intensity and a wavelength of the first combined wave.

8. The wavelength monitoring method according to claim 7, wherein the first excitation structure is formed by optically connecting the first optical waveguide and a second optical waveguide through which the first-mode light and the second-mode light propagate by shifting, by a predetermined amount, an optical axis of the first optical waveguide and an optical axis of the second optical waveguide in a direction orthogonal to the optical axis of the first optical waveguide and the optical axis of the second optical waveguide.

9. The wavelength monitoring method according to claim 7, further comprising:
splitting the single-mode light into first light and reference light that have a predetermined light intensity ratio, and outputting the first light to the first optical waveguide; and
receiving the reference light by a light receiver,
correcting the light intensity of the first combined wave received by the first light receiver, based on the light intensity of the reference light received by the light receiver.

10. The wavelength monitoring method according to claim 7, further comprising:
splitting the single-mode light into a plurality of beams of light having a predetermined light intensity ratio, outputting first light among the plurality of beams of light to the first optical waveguide, and outputting second light;
by a second excitation structure, exciting the first-mode light and the second-mode light from the second light propagating through a third optical waveguide configured to guide the second light;
by a second light receiver, receiving a second combined wave acquired by combining the first-mode light and the second-mode light that are excited by the second excitation structure that are propagated through a fourth optical waveguide being shorter than the second optical waveguide;
performing processing of determining a wavelength of the single-mode light associated with light intensity of the second combined wave received by the second light receiver, based on information being acquired in advance and indicating a correspondence relationship between the light intensity and a wavelength of the second combined wave received by the second light receiver; and
determining, based on the processing, information to be referred to among a correspondence relationship, being acquired in advance, between the light intensity and a wavelength of the first combined wave received by the first light receiver, and determines, based on the determined information, a wavelength of the single-mode light associated with the light intensity of the first combined wave received by the first light receiver.

11. The wavelength monitoring method according to claim 10, wherein the second excitation structure is formed by optically connecting the third optical waveguide and the fourth optical waveguide by shifting, by a predetermined amount, an optical axis of the third optical waveguide and an optical axis of the fourth optical waveguide in a direction orthogonal to the optical axis of the third optical waveguide and the optical axis of the fourth optical waveguide.

12. The wavelength monitoring method according to claim 10, further comprising:
by light receiver, receiving reference light among the plurality of beams of light; and
correcting light intensity of the first combined wave received by the first light receiver and light intensity of the second combined wave received by the second light receiver, based on light intensity of the reference light received by the light receiver.

13. A wavelength locker comprising:
a wavelength tunable light source configured to output light of a single mode;
a wavelength monitoring apparatus configured to monitor a wavelength of the single-mode light being output from the wavelength tunable light source, and output a monitoring result; and
a wavelength control device for instructing the wavelength tunable light source to control a wavelength of the single-mode light to be output, according to the monitoring result,
wherein the wavelength monitoring apparatus includes
a first optical waveguide configured to guide the single-mode light being output from the wavelength tunable light source,
a first excitation structure configured to excite light of a first mode and light of a second mode that are different from each other, from the single-mode light propagating through the first optical waveguide,
a second optical waveguide through which the first-mode light and the second-mode light propagate,
a first light receiver configured to receive a first combined wave acquired by combining the first-mode light and the second-mode light, and
a wavelength analysis unit configured to determine a wavelength of the single-mode light associated with light intensity of the first combined wave received by the first light receiver, based on information being acquired in advance and indicating a correspondence relationship between the light intensity and a wavelength of the first combined wave received by the first light receiver.

14. The wavelength locker according to claim 13, wherein the first excitation structure is formed by optically connecting the first optical waveguide and the second optical waveguide by shifting, by a predetermined amount, an optical axis of the first optical waveguide and an optical axis of the second optical waveguide in a direction orthogonal to the optical axis of the first optical waveguide and the optical axis of the second optical waveguide.

15. The wavelength locker according to claim 13, further comprising:
a splitter configured to split the single-mode light into first light and reference light that have a predetermined light intensity ratio, and outputting the first light to the first optical waveguide; and
a light receiver configured to receive the reference light,
wherein the wavelength analysis unit corrects the light intensity of the first combined wave received by the first light receiver, based on the light intensity of the reference light received by the light receiver.

16. The wavelength locker according to claim 13, further comprising:
a splitter configured to split the single-mode light into a plurality of beams of light having a predetermined light intensity ratio, outputting first light among the plurality of beams of light to the first optical waveguide, and outputting second light;
a third optical waveguide configured to guide the second light;
a second excitation structure configured to excite the first-mode light and the second-mode light from the second light propagating through the third optical waveguide;
a fourth optical waveguide through which the first-mode light and the second-mode light that are excited by the second excitation structure propagate, the fourth optical waveguide being shorter than the second optical waveguide; and
a second light receiver configured to receive a second combined wave acquired by combining the first-mode light and the second-mode light that are propagated through the fourth optical waveguide,
wherein the wavelength analysis unit
performs processing of determining a wavelength of the single-mode light associated with light intensity of the second combined wave received by the second light receiver, based on information being acquired in advance and indicating a correspondence relationship between the light intensity and a wavelength of the second combined wave received by the second light receiver, and
determines, based on the processing, information to be referred to among a correspondence relationship, being acquired in advance, between the light intensity and a wavelength of the first combined wave received by the first light receiver, and determines, based on the determined information, a wavelength of the single-mode light associated with the light intensity of the first combined wave received by the first light receiver.

17. The wavelength locker according to claim 16, wherein the second excitation structure is formed by optically connecting the third optical waveguide and the fourth optical waveguide by shifting, by a predetermined amount, an optical axis of the third optical waveguide and an optical axis of the fourth optical waveguide in a direction orthogonal to the optical axis of the third optical waveguide and the optical axis of the fourth optical waveguide.

18. The wavelength locker according to claim 16, further comprising light receiver configured to receive reference light among the plurality of beams of light,
wherein the wavelength analysis unit corrects light intensity of the first combined wave received by the first light receiver and light intensity of the second combined wave received by the second light receiver, based on light intensity of the reference light received by the light receiver.
